(19) United States
(12) Patent Application Publication
(10) Pub. No.: US 2026/0129756 A1
(43) Pub. Date: May 7, 2026

(54) PRINTED CIRCUIT BOARD

(71) Applicant: SAMSUNG ELECTRO-MECHANICS CO., LTD., Suwon-si (KR)

(72) Inventor: Song I Kim, Suwon-si (KR)

(73) Assignee: SAMSUNG ELECTRO-MECHANICS CO., LTD., Suwon-si (KR)

(21) Appl. No.: 19/174,823

(22) Filed: Apr. 9, 2025

(30) Foreign Application Priority Data
Nov. 4, 2024 (KR) 10-2024-0154403

(51) Int. Cl. H05K 1/11; H05K 1/02; H05K 1/03; H05K 1/18

(52) U.S. Cl. CPC H05K 1/116; H05K 1/0298; H05K 1/032; H05K 1/183; H05K 2201/09036

(57) ABSTRACT

A printed circuit board includes a glass layer having a first surface and a second surface opposing each other in a first direction, a through-via passing through at least a portion of a space between the first and second surfaces of the glass layer, a first pad embedded in the first surface of the glass layer, the first pad connected to one end of the through-via in the first direction, and a second pad protruding from the second surface of the glass layer, the second pad connected to the other end of the through-via in the first direction. The first and second pads have different structures and/or arrangements.

### CROSS-REFERENCE TO RELATED APPLICATION(S)

This application claims benefit of priority to Korean Patent Application No. 10-2024-0154403 filed on Nov. 4, 2024 in the Korean Intellectual Property Office, the disclosure of which is incorporated herein by reference in its entirety.

### TECHNICAL FIELD

The present disclosure relates to a printed circuit board.

An interposer, a type of intermediate substrate used in semiconductor packaging technology, may include a rewiring layer on a portion thereof generally connected to a chip for electrical connection between a chip and a substrate having a large pitch difference. Accordingly, upper and lower portions of the interposer may be asymmetrical with respect to each other. In this case, there may be a limitation in controlling occurrence of warpage.

### SUMMARY

An aspect of the present disclosure provides a printed circuit board capable of easily controlling warpage even in an asymmetrical structure.

A glass layer having a through-via may be used, and both pads of the through-via may have different arrangements and structures.

According to an aspect of the present disclosure, there is provided a printed circuit board including a glass layer having a first surface and a second surface opposing each other in a first direction, a through-via passing through at least a portion of a space between the first and second surfaces of the glass layer, the through-via having a first end and a second end opposing the first end in the first direction, a first pad embedded in the first surface of the glass layer, the first pad connected to the first end of the through-via, and a second pad protruding from the second surface of the glass layer, the second pad connected to the second end of the through-via.

According to another aspect of the present disclosure, there is provided a printed circuit board including a glass layer having a first surface and a second surface opposing each other in a first direction, a through-via passing through at least a portion of a space between the first and second surfaces of the glass layer, the through-via having a first end and a second end opposing the first end in the first direction, a first pad disposed on the first surface of the glass layer, the first pad connected to the first end of the through-via, and a second pad disposed on the second surface of the glass layer, the second pad connected to the second end of the through-via. The first pad and the second pad may be asymmetrical with respect to each other and with respect to a central line between the first surface and the second surface of the glass layer.

According to example embodiments of the present disclosure, a printed circuit board may easily control warpage even in an asymmetrical structure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board;

FIG. 3 is a schematic process cross-sectional view of an example of manufacturing a through-via and first and second pads included in the printed circuit board of FIG. 2;

FIG. 4 is a schematic process cross-sectional view of an example of operation B of FIG. 3;

FIG. 5 is a schematic process cross-sectional view of another example of operation B of FIG. 3; and

FIG. 6 is a schematic cross-sectional view of another example of a printed circuit board.

### DETAILED DESCRIPTION

Hereinafter, example embodiments of the present disclosure are described with reference to the accompanying drawings. The shapes and sizes of components in the drawings may be exaggerated or reduced for clearer description.

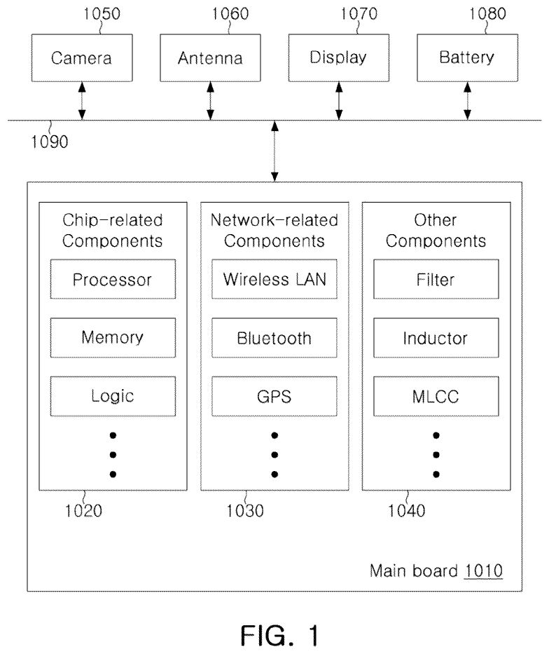

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

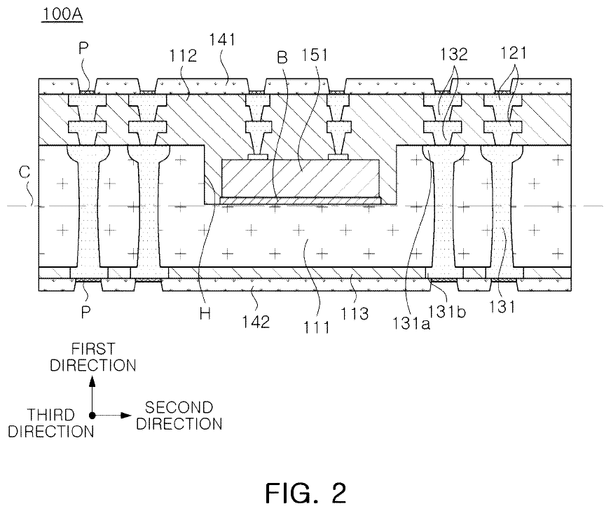

FIG. 2 is a schematic perspective view of an example of an electronic device.

Referring to the drawings, a printed circuit board 100A according to an example may include a glass layer 111 having a first surface and a second surface opposing each other in a first direction, a through-via 131 passing through at least a portion of a space between the first surface and the second surface of the glass layer 111, a first pad 131a disposed on the first surface of the glass layer 111, the first pad 131a connected to one end (first end) of the through-via 131 in the first direction, and a second pad 131b disposed on the second surface of the glass layer, the second pad 131b connected to the other end (second end) of the through-via 131 in the first direction. The first and second pads 131a and 131b may have different structures and/or arrangements. For example, the first and second pads 131a and 131b may be asymmetrical with respect to each other with respect to a central line C between the first surface and the second surface of the glass layer 111.

As described above, the printed circuit board 100A according to an example may include the glass layer 111 in which the through-via 131 is formed. In this case, the first and second pads 131a and 131b, formed at both sides of the through-via 131, may have different structures and/or arrangements. Accordingly, even when build-up layers are formed to be asymmetrical with respect to each other with respect to the glass layer 111, a neutral axis generated by a coefficient of thermal expansion mismatch in an asymmetrical structure may be moved toward a smaller number of layers, thereby implementing a structure advantageous for improving warpage. In this case, a degree of design freedom, such as the number of layers of a wiring and a via formed in the build-up layer, may be secured. Accordingly, the printed circuit board 100A may be easily applied to, for example, a substrate having asymmetric upper and lower portions, for example, an interposer substrate.

The first pad 131a may be embedded in the first surface of the glass layer 111, and the second pad 131b may protrude from the second surface of the glass layer 111. Accordingly, a distance between the first pad 131a and the central line C in the first direction may be shorter than a distance between the second pad 131b and the central line C in the first direction. For example, a distance between an outermost surface of the first pad 131a and the central line C in the first direction may be shorter than a distance between an outermost surface of the second pad 131b and the central line C in the first direction. In this case, in an asymmetrical structure in which a greater number of build-up layers are formed on the first surface of the glass layer 111, a neutral axis generated by a coefficient of thermal expansion mismatch may be moved downwardly, which may be more advantageous for improving warpage. In addition, an overall thickness of the substrate may be reduced through the embedded first pad 131a.

Each of a side surface (first surface) and a bottom surface (second surface) of the first pad 131a may have a substantially rounded shape. Conversely, each of a side surface and a bottom surface of the second pad 131b may have a substantially flat shape. For example, a surface of the first pad 131a, connected to one end portion of the through-via 131, may have a substantially rounded shape. Conversely, a surface of the second pad 131b, connected to the other end portion of the through-via 131, may have a substantially flat shape. Such a structural feature may easily resolve an issue associated with connectivity and reliability, caused by a dimple, which may generally occur when a through-glass via (TGV) is formed. In addition, a bonding area in an alignment process between a via and a pad may be sufficiently secured using the first and second pads 131a and 131b, thereby further improving reliability.

As necessary, the printed circuit board 100A according to an example may further include a first insulating body 112 disposed on the first surface of the glass layer 111, a second insulating body 113 disposed on or in the second surface of the glass layer 111, a plurality of first wiring layers 121 respectively disposed on or in the first insulating body 112, and a plurality of first via layers 132 respectively disposed in the first insulating body 112, the plurality of first via layers 132 respectively connected to one or more of the plurality of first wiring layers 121. The first insulating body 112 may be thicker than the second insulating body 113 in the first direction. The printed circuit board 100A according to an example may have an asymmetric interposer structure in which a build-up layer and a wiring layer are formed to be deflected toward the first surface of the glass layer 111.

As necessary, the printed circuit board 100A according to an example may further include a first resist layer 141 disposed on the first insulating body 112 to cover at least a portion of an outermost first wiring layer 121 in the first direction, among the plurality of first wiring layers 121, and to expose at least another portion of the outermost first wiring layer 121 in the first direction, and a second resist layer 142 disposed on the second insulating body 112 to cover at least a portion of the second pad 131b and to expose at least another portion of the second pad 131b. A surface treatment layer P may be disposed on each of the at least another portion of the outermost first wiring layer 121 exposed through the first resist layer 141 and the at least another portion of the second pad 131b exposed through the second resist layer 142, respectively. The surface treatment layer P may include one or more of hot air solder leveling (HASL), electroless nickel immersion gold (ENIG), organic solderability preservative (OSP), immersion silver (imAg), and immersion tin (imSn).

As necessary, the printed circuit board 100A according to an example may have a cavity H in which the glass layer 111 passes through at least a portion of the glass layer 111 from the first surface of the glass layer 111 in the first direction. At least a portion of the first electronic component 151 may be disposed in the cavity H. The first electronic component 151 may be attached to a rear surface of the cavity H using an adhesive film B. The adhesive film B may be a die attach film (DAF), but the present disclosure is not limited thereto. The first insulating body 112 may cover at least a portion of the first electronic component 151, and may fill at least a portion of the cavity H. The first electronic component 151 may be connected to one or more of a plurality of first wiring layers 121 through one or more of a plurality of first via layers 132. As described, the first electronic component 151 may be embedded in the printed circuit board 100A according to an example, and thus the cavity H of the glass layer 111 may be used, thereby further reducing an overall thickness of a product to which the printed circuit board 100A is applied, and more easily achieving high performance of the product.

Hereinafter, components of the printed circuit board 100A according to an example will be described in more detail with reference to the drawings.

The glass layer 111 may include glass that is an amorphous solid. Glass may include, for example, pure silicon dioxide (about 100% SiO₂), soda lime glass, borosilicate glass, alumino-silicate glass, or the like, but the present disclosure is not limited thereto. An alternative glass material, such as fluorine glass, phosphate glass, chalcogen glass, or the like, may also be used as a material of the glass layer. In addition, other additives may be further included to form glass having specific physical properties. The above-described additives may include calcium carbonate (for example, lime) and sodium carbonate (for example, soda), as well as magnesium, calcium, manganese, aluminum, lead, boron, iron, chromium, potassium, sulfur, and antimony, and carbonates and/or oxides of the above-described elements and other elements. The glass layer 111 may be distinguished from an organic insulating material including a glass fiber (glass cloth and/or glass fabric), for example, a copper clad laminate (CCL), a prepreg (PPG), or the like. The glass layer 111 may be, for example, in the form of a glass plate.

Each of the first and second insulating bodies 112 and 113 may include an organic insulating material. The organic insulating material may include a thermosetting resin such as an epoxy resin, a thermoplastic resin such as polyimide, or an inorganic filler, an organic filler, and/or a glass fiber (glass cloth and/or glass fabric), together with the resin. For example, the organic insulating material may be a PPG, an Ajinomoto build-up film (ABF), a photoimageable dielectric (PID) or the like, but the present disclosure is not limited thereto. The first and second insulating bodies 112 and 113 may be asymmetrical with respect to each other. For example, the number of insulating layers included in the first insulating body 112 may be greater than the number of insulating layers included in the second insulating body 113. A plurality of insulating layers, included in the first insulating body 112, may not be distinguished from each other, but the present disclosure is not limited thereto, and may be distinguished from each other, as necessary. The first and second insulating bodies 112 and 113 may include substantially the same organic insulating material, but the present disclosure is not limited thereto, and may also include different organic insulating materials.

The first wiring layer 121 may include a metal. The metal may include copper (Cu), aluminum (Al), silver (Ag), tin (Sn), gold (Au), nickel (Ni), lead (Pb), titanium (Ti), and/or alloys thereof. For example, the first wiring layer 121 may include a chemical copper, formed using electroless plating, as a seed layer, and may include an electrolytic copper, formed using electrolytic plating based on the same, as a pattern plating layer, but the present disclosure is not limited thereto. The first wiring layer 121 may include a titanium (Ti) layer and a copper (Cu) layer, formed using sputtering, as a plurality of seed layers, as necessary. The first wiring layer 121 may perform various functions according to a design thereof. For example, a signal pattern, a power pattern, a ground pattern, or the like may be included. The patterns may be respectively in various forms, such as a line, a trace, a plane, a pad, and the like. The pad may be based on a concept including a land. The first wiring layer 121 may include a plurality of layers, and the above-described description may be applied to each of the plurality of layer.

The through-via 131 may include a metal. The metal may include copper (Cu), aluminum (Al), silver (Ag), tin (Sn), gold (Au), nickel (Ni), lead (Pb), titanium (Ti), and/or alloys thereof. For example, the through-via 131 may include a titanium (Ti) layer and a copper (Cu) layer, formed using sputtering, as a plurality of seed layers, and may include an electrolytic copper, formed using electrolytic plating based on the same, as a fill plating layer, but the present disclosure is not limited thereto, and may include a chemical copper, formed using electroless plating, as a seed layer, as necessary. The through-via 131 may perform various functions according to a design thereof. For example, a signal via, a power via, a ground via, or the like may be included. As necessary, a length of the through-via 131 in the first direction may be relatively shorter than a length of the glass layer 111 in the first direction. For example, both ends of the through-via 131 in the first direction may be partially recessed with respect to the first surface and the second surface of the glass layer 111. The through-via 131 may have a tapered side surface, for example, an hourglass shape, in cross-section in the first direction and a second direction, but the present disclosure is not limited thereto, and may have a cylindrical shape having an approximately vertical side surface. The through-via 131 may be a through-glass via (TGV). The through-via 131 may be provided as a plurality of through-vias 131, and the plurality of through-vias 131 may be disposed to be spaced apart from each other in the second direction.

The first and second pads 131a and 131b may include a metal. The metal may include copper (Cu), aluminum (Al), silver (Ag), tin (Sn), gold (Au), nickel (Ni), lead (Pb), titanium (Ti), and/or alloys thereof. For example, the first and second pads 131a and 131b may include a titanium (Ti) layer and a copper (Cu) layer, formed using sputtering, as a plurality of seed layers, respectively, and may include an electrolytic copper formed based on the same using electrolytic plating, as a pattern plating layer, but the present disclosure is not limited thereto. The first and second pads 131a and 131b may include a chemical copper, formed using electroless plating, as a seed layer, as necessary. Each of the first and second pads 131a and 131b may perform various functions according to a design thereof. For example, a signal pad, a power pad, a ground pad, or the like may be included.

The first via layer 132 may include a metal. The metal may include copper (Cu), aluminum (Al), silver (Ag), tin (Sn), gold (Au), nickel (Ni), lead (Pb), titanium (Ti), and/or alloys thereof. For example, the first via layer 132 may include a chemical copper, formed using electroless plating, as a seed layer, and may include an electrolytic copper, formed using electrolytic plating, as a via plating layer, but the present disclosure is not limited thereto. The first via layer 132 may include a titanium (Ti) layer and a copper (Cu) layer, formed using sputtering, as a plurality of seed layers, as necessary. The first via layer 132 may perform various functions according to a design thereof. For example, a signal via, a power via, a ground via, or the like may be included. The first via layer 132 may include a filled via in which a via hole is filled with a metal, but may include a conformal via in which a metal is disposed along a wall surface of a via hole. The first via layer 132 may have a tapered shape, in cross-section in the first direction and the second direction. The first via layer 132 may include a plurality of layers, and the above description may be applied to each of the plurality of layers.

Each of the first and second resist layers 141 and 142 may include an organic insulating material. The organic insulating material may include a thermosetting resin such as an epoxy resin, a thermoplastic resin such as polyimide, or an inorganic filler and/or an organic filler, together with the resin. For example, the organic insulating material may be an ABF, a PID, a solder resist (SR), or the like, but the present disclosure is not limited thereto. Each of the first and second resist layers 141 and 142 may include a plurality of layers. The first resist layer 141 may have an opening, exposing the outermost first wiring layer 121 in the first direction. The second resist layer 142 may have an opening, exposing the second pad 131b. Each opening may be a plurality of openings. A portion, exposed through an opening, may be a solder mask defined (SMD) and/or a non-solder mask defined (NSMD)-type portion.

The first electronic component 151 may be various types of active components and/or passive components. For example, the first electronic component 151 may include an integrated circuit device (ICD), an embedded passive integrated component (EPIC), and the like, but the present disclosure is not limited thereto. The first electronic component 151 may be attached to a bottom surface of the cavity H using the adhesive film B, and thus may be disposed in a face-up form. A surface of the first electronic component 151, opposite to a surface thereof connected to the bottom surface of the cavity H, may have a plurality of connection pads. The plurality of connection pads may include a metal such as copper (Cu), aluminum (Al), or the like. Each of the plurality of connection pads may be connected to an innermost first wiring layer 121 in the first direction through an innermost first via layer 132 in the first direction.

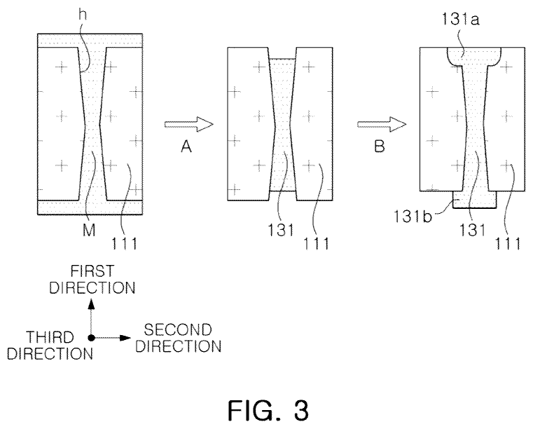

FIG. 3 is a schematic process cross-sectional view of an example of manufacturing a through-via and first and second pads included in the printed circuit board of FIG. 2.

Referring to the drawings, first, a through-hole h may be formed in the glass layer 111 using etching, blasting, laser, plasma, or the like, a seed layer including a titanium (Ti) layer and a copper (Cu) layer may be formed on inner walls of the glass layer 111 and the through-hole h using sputtering, and a plating layer including an electrolytic copper may be formed using electrolytic plating. The glass layer 111 in which the through-hole h is formed may be entirely covered with and filled with a metal layer M using a series of processes.

Subsequently, the metal layer M on the first surface and the second surface of the glass layer 111 may be removed by performing a polishing process such as chemical mechanical polishing (CMP) or the like. In this case, a dimple or a recess may be formed in each of one end and the other end of the through-hole h. For example, the first surface and the second surface of the glass layer 111 may have step portions with respect to one end and the other end of the through-via 131 formed after the polishing process.

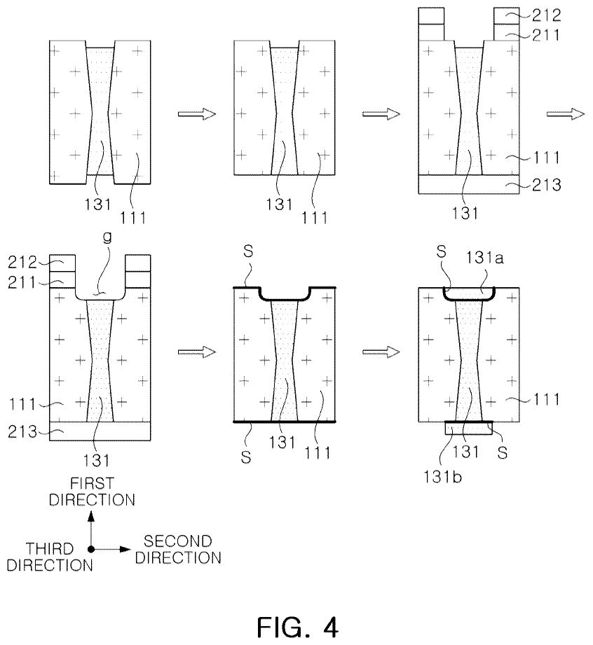

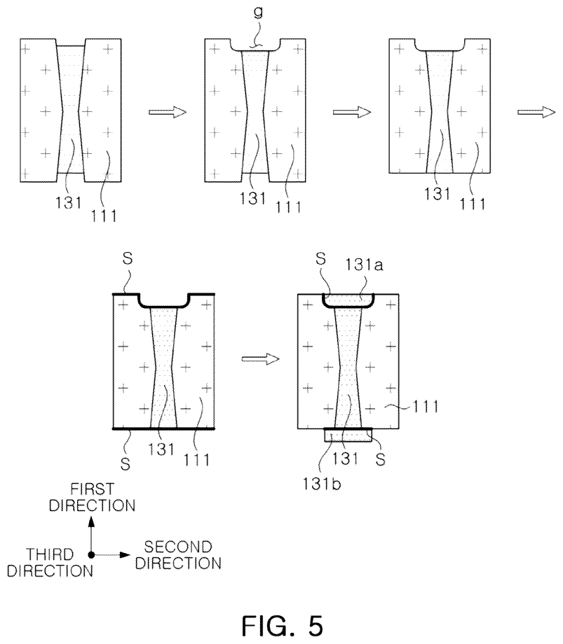

Subsequently, a first pad 121a that is in the form of an embedded pad, connected to one end of the through-via 131 in the first direction, may be formed. In addition, a second pad 121b that is in the form of a protruding pad, connected to the other end of the through-via 131 in the first direction, may be formed. A more detailed description thereof will be given below with reference to FIGS. 4 and 5. As described, the first and second pads 131a and 131b may be formed at both end portions of the through-via 131, thereby improving warpage by adjusting a neutral axis having an asymmetrical structure, reducing an overall thickness, and improving reliability with a connection via, as described above.

FIG. 4 is a schematic process cross-sectional view of an example of operation B of FIG. 3.

Referring to the drawings, first, the glass layer 111 at the other end of the through-via 131 may be polished using a single-sided glass polishing process. For example, a thickness of the glass layer 111 in a first direction may be reduced. In addition, the other end of the through-via 131 may be substantially coplanar with the second surface of the glass layer 111. Conversely, one end of the through-via 131 may maintain a step portion with respect to the second surface of the glass layer 111.

Subsequently, a first masking film 211, patterned to expose the one end of the through-via 131, may be disposed on the first surface of the glass layer 111, and a cover film 212, patterned similarly to the first masking film 211, may be disposed on the first masking film 211. In addition, a second masking film 213, covering the other end of the through-via 131, may be disposed on the second surface of the glass layer 111. A release layer may be disposed between the first masking film 211 and the cover film 212. The cover film 212 may have chemical resistance.

Subsequently, etching treatment may be performed on the exposed first surface of the glass layer 111 and the exposed one end of the through-via 131. A portion of the glass layer 111 and a portion of the through-via 131 may be removed using etching, and a groove portion g may be formed on the one end of the through-via 131. Thereafter, the first and second masking films 211 and 213 and the cover film 212 may be peeled and removed using a mechanical method and/or a chemical method.

Subsequently, a seed layer S, covering the first and second surfaces of the glass layer 111, a wall surface of the groove portion g, and the one end and the other end of the through-via 131, may be formed. The seed layer S may be formed using sputtering. For example, a titanium (Ti) layer and a copper (Cu) layer may be sequentially formed using sputtering, but the present disclosure is not limited thereto. The seed layer S including a chemical copper may be formed using electroless plating, as necessary. Alternatively, a combination of both may be used.

Subsequently, a plating layer including an electrolytic copper may be formed on the seed layer S using electrolytic plating to form first and second pads 131a and 131b. The first pad 131a may be in the form of an embedded pad, and the second pad 131b may be in the form of a protruding pad. The first pad 131a may have a side surface and a bottom surface respectively having a substantially rounded shape, and the second pad 131b may have a side surface and a bottom surface respectively having a substantially flat shape. The seed layer S may be disposed between the one end and the other end of the through-via 131 and between the bottom surfaces of the first and second pads 131a and 131b. As described, the seed layer S may be disposed between the through-via 131 and the first and second pads 131a and 131b, and thus connection reliability between the through-via 131 and the first and second pads 131a and 131b may be more excellent.

FIG. 5 is a schematic process cross-sectional view of another example of operation B of FIG. 3.

Referring to the drawings, first, a groove portion g may be formed by processing the first surface of the glass layer 111 and one end of the through-via 131 with a laser beam. For example, the groove portion g having a desired shape may be formed as the glass layer 111 is carved using laser processing. Accordingly, in another example, the groove portion g may have more various shapes in addition to the structure illustrated in the drawings, and as a result, the first pad 131a may also have more various shapes. A portion of the glass layer 111 and a portion of the through-via 131 may be removed using laser processing.

Subsequently, the glass layer 111 at the other end of the through-via 131 may be polished using a single-sided glass polishing process. For example, a thickness of the glass layer 111 in a first direction may be reduced. In addition, the other end of the through-via 131 may be substantially coplanar with the second surface of the glass layer 111. Conversely, the one end of the through-via 131 may maintain a step portion with respect to the second surface of the glass layer 111.

Subsequently, a seed layer S, covering the first and second surfaces of the glass layer 111, a wall surface of the groove portion g, and the one end and the other end of the through-via 131, may be formed. The seed layer S may be formed using sputtering. For example, a titanium (Ti) layer and a copper (Cu) layer may be sequentially formed using sputtering, but the present disclosure is not limited thereto. The seed layer S including a chemical copper may be formed using electroless plating, as necessary. Alternatively, a combination of both may be used.

Subsequently, a plating layer including an electrolytic copper may be formed on the seed layer S using electrolytic plating to form first and second pads 131a and 131b. The first pad 131a may be in the form of an embedded pad, and the second pad 131b may be in the form of a protruding pad. The first pad 131a may have a side surface and a bottom surface respectively having a substantially rounded shape, and the second pad 131b may have a side surface and a bottom surface respectively having a substantially flat shape. The seed layer S may be disposed between the one end and the other end of the through-via 131 and between the bottom surfaces of the first and second pads 131a and 131b. As described, the seed layer S may be disposed between the through-via 131 and the first and second pads 131a and 131b, and thus connection reliability between the through-via 131 and the first and second pads 131a and 131b may be more excellent.

The formation processes, the final structures, and the technical effect of the glass layer 111, the through-via 131, the groove portion g, the first and second pads 131a and 131b, and the seed layer S, described with reference to FIGS. 3 to 5, may be applied to the printed circuit board 100A of FIG. 2 in substantially the same manner.

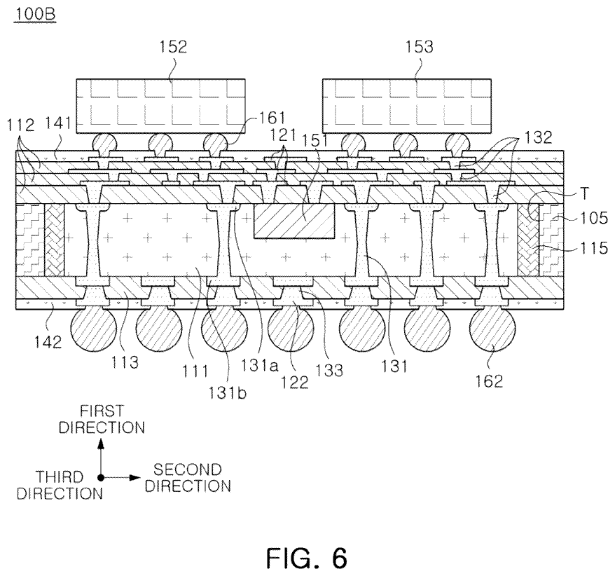

FIG. 6 is a schematic cross-sectional view of another example of a printed circuit board.

Referring to the drawings, a printed circuit board 100B according to another example may include a frame 105 having a through-portion T, a glass layer 111 having at least a portion disposed in the through-portion T of the frame 105, the glass layer 111 having a first surface and a second surface opposing each other in a first direction, a filler 115 filling at least a portion of a space between the frame 105 and the glass layer 111, a through-via 131 passing through at least a portion of a space between the first surface and the second surface of the glass layer 111, a first pad 131a disposed on the first surface of the glass layer 111, the first pad 131a connected to one end of the through-via 131 in the first direction, and a second pad 131b disposed on the second surface of the glass layer 111, the second pad 131b connected to the other end of the through-via 131 in the first direction.

In addition, the printed circuit board 100B according to another example may further include a plurality of first insulating layers 112 disposed on the first surface of the glass layer 111, a second insulating layer 113 disposed on the second surface of the glass layer 111, a plurality of first wiring layers 121 respectively disposed on or in the plurality of first insulating layers 112, a second wiring layer 122 disposed on or in the second insulating layer 113, a plurality of first via layers 132 respectively disposed in the plurality of first insulating layers 112, the plurality of first via layers 132 respectively connected to one or more of the plurality of first wiring layers 121, a second via layer 133 disposed in the second insulating layer 113, the second via layer 133 connected to the second wiring layer 122, a first resist layer 141 disposed on the plurality of first insulating layers 112 to cover at least a portion of an outermost first wiring layer 121 in the first direction and to expose at least another portion of the outermost first wiring layer 121 in the first direction, and a second resist layer 142 disposed on the second insulating layer 113 to cover at least a portion of the second wiring layer 122 and to expose at least another portion of the second wiring layer 122.

In addition, the printed circuit board 100B according to another example may further include a first electronic component 151 embedded in the glass layer 111, the first electronic component 151 connected to an innermost first wiring layer 121 in the first direction through an innermost first via layer 132 in the first direction, a plurality of second electronic components 152 and 153 respectively disposed on the first resist layer 141, the plurality of second electronic components 152 and 153 respectively connected to the exposed at least another portion of the outermost first wiring layer 121 in the first direction through a plurality of first electrical connection metals 161, and a plurality of second electrical connection metals 162 respectively disposed on the second resist layer 142, the plurality of second electrical connection metals 162 respectively connected to the exposed at least another portion of the second wiring layer 122.

Hereinafter, components of the printed circuit board 100B according to another example will be described in more detail with reference to the drawings.

The frame 105 may include a material having excellent rigidity, and may include, for example, a CCL or an unclad CCL, but the present disclosure is not limited thereto. The frame 105 may be used as a jig in a process, and thus, the process may be performed at a panel level through the frame 105. In addition, the frame 105 may remain in a final unit after singulation, and thus may be advantageous for warpage control. The frame 105 may continuously surround the glass layer 111 in second and third directions. For example, the through-portion T may be formed to have a continuous wall surface.

The filler 115 may include an organic insulating material. The organic insulating material may include a thermosetting resin such as an epoxy resin, a thermoplastic resin such as polyimide, or a material including an inorganic filler and/or an organic filler, together with the resin. For example, the organic insulating material may include an ABF, a PID, a bonding sheet (BS), or the like. The filler 115 may be integrated with an innermost first insulating layer 112 in the first direction, as necessary. For example, a space between the frame 105 and the glass layer 111 may be filled with the innermost first insulating layer 112. In this case, the filler 115 may be a portion of the innermost first insulating layer 112, but the present disclosure is not limited thereto. The filler 115 may be formed of other materials.

Each of the plurality of first insulating layers 112 and the second insulating layer 113 may include an organic insulating material. The organic insulating material may include a thermosetting resin such as an epoxy resin, a thermoplastic resin such as polyimide, or an inorganic filler, an organic filler, and/or a glass fiber (glass cloth and/or glass fabric), together with the resin. For example, the organic insulating material may be a PPG, an ABF, a PID or the like, but is not limited thereto. The plurality of first insulating layers 112 and the second insulating layer 113 may include substantially the same insulating material. The number of layers of the plurality of first insulating layers 112 may be greater than the number of layers of the second insulating layer 113. For example, the glass layer 111 may have an asymmetrical structure, and may have a greater number of layers in a direction in which the plurality of second electronic components 152 and 153 are mounted.

Each of the plurality of first wiring layers 121 and the second wiring layer 122 may include a metal. The metal may include copper (Cu), aluminum (Al), silver (Ag), tin (Sn), gold (Au), nickel (Ni), lead (Pb), titanium (Ti), and/or alloys thereof. For example, the plurality of first wiring layers 121 and the second wiring layer 122 may respectively include a chemical copper, formed using electroless plating, as a seed layer, and may include an electrolytic copper, formed using electrolytic plating based on the same, as a pattern plating layer, but the present disclosure is not limited thereto. The plurality of first wiring layers 121 and the second wiring layer 122 may include a titanium (Ti) layer and a copper (Cu) layer formed using sputtering, as a plurality of seed layers, as necessary. Each of the plurality of first wiring layers 121 and the second wiring layer 122 may perform various functions according to a design thereof. For example, a signal pattern, a power pattern, a ground pattern, or the like may be included. The patterns may be respectively in various forms, such as a line, a trace, a plane, a pad, and the like. The pad may be based on a concept including a land. The number of layers of the plurality of first wiring layers 121 may be greater than the number of layers of the second wiring layer 122. For example, the glass layer 111 may have an asymmetrical structure, and may have a greater number of layers in a direction in which the plurality of second electronic components 152 and 153 are mounted.

Each of the plurality of first via layers 132 and the second via layer 133 may include a metal. The metal may include copper (Cu), aluminum (Al), silver (Ag), tin (Sn), gold (Au), nickel (Ni), lead (Pb), titanium (Ti), and/or alloys thereof. For example, the plurality of first via layers 132 and the second via layer 133 may respectively include a chemical copper, formed using electroless plating, as a seed layer, and may include an electrolytic copper, formed using electrolytic plating based on the same, as a via plating layer, but the present disclosure is not limited thereto. The plurality of first via layers 132 and the second via layer 133 may include a titanium (Ti) layer and a copper (Cu) layer, formed using sputtering, as a plurality of seed layers, as necessary. Each of the plurality of first via layers 132 and the second via layer 133 may perform various functions according to a design thereof. For example, a signal via, a power via, a ground via, or the like may be included. Each of the plurality of first via layers 132 and the second via layer 133 may include a filled via in which a via hole is filled with a metal, but may include a conformal via in which a metal is disposed along a wall surface of a via hole. Each of the plurality of first via layers 132 and the second via layer 133 may have a tapered shape in cross-section in the first direction and the second direction, for example, may be tapered in opposite directions. The number of layers of a plurality of first via layers 132 may be greater than the number of layers of the second via layer 133. For example, the glass layer 111 may have an asymmetrical structure, and may have a greater number of layers in a direction in which the plurality of second electronic components 152 and 153 are mounted.

The first electronic component 151 may be various types of active components and/or passive components. For example, the first electronic component 151 may include an ICD, an EPIC, and the like, but the present disclosure is not limited thereto. The first electronic component 151 may be embedded in the glass layer 111, and a detailed structure thereof may be the same as that of the above-described printed circuit board 100A according to an example, but the present disclosure is not limited thereto. Embedding may be performed in various other forms.

Each of the plurality of second electronic components 152 and 153 may include an active component and/or a passive component. The active component may include various types of semiconductor chips, and the passive component may include various types of chip-type components such as chip capacitors and chip inductors. Each semiconductor chip may include an integrated circuit (IC) die in which hundreds to millions of devices are integrated into a single chip. In this case, the integrated circuit may be, for example, a logic chip such as a central processing unit (for example, a CPU), a graphics processing unit (for example, a GPU), a field programmable gate array (FPGA), a digital signal processor, a cryptographic processor, a microprocessor, a microcontroller, an application processor (for example, an AP), an analog-to-digital converter, an application-specific IC (ASIC), or the like, but the present disclosure is not limited thereto, and may also be a memory chip such as a volatile memory (for example, DRAM), a non-volatile memory (for example, ROM), a flash memory, a high bandwidth memory (HBM), or the like, or a power management IC (PMIC).

Each of the plurality of first and second electrical connection metals 161 and 162 may be formed of a low melting point metal, for example, solder such as tin (Sn)-aluminum (Al)-copper (Cu), or the like, but the material is only an example and is not limited thereto. Each of the plurality of first and second electrical connection metals 161 and 162 may be a ball, a pin, or the like. Each of the plurality of first and second electrical connection metals 161 and 162 may be formed of multiple layers or a single layer. Each of the plurality of first and second electrical connection metals 161 and 162 may include a copper pillar and solder when formed of multiple layers, and may include tin-silver solder when formed of a single layer, but the present disclosure is not limited thereto. The plurality of first electrical connection metals 161 may be used for mounting the plurality of second electronic components 152 and 153, and the plurality of second electrical connection metals 162 may be used for mounting the printed circuit board 100B according to another example on another substrate such as a main board.

The descriptions and the technical effect of the glass layer 111, the through-via 131, the first and second pads 131a and 131b, and the first and second resist layers 141 and 142 of the printed circuit board 100A according to an example described with reference to FIG. 2 may be applied to the printed circuit board 100B according to another example in substantially the same manner. In addition, the formation processes, the final structures, and the technical effect of forming the glass layer 111, the through-via 131, the first and second pads 131a and 131b, the groove portion g, and the seed layer S, described with reference to FIGS. 3 to 5, may be applied to the printed circuit board 100B according to another example in substantially the same manner.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is embedded. In addition, being adjacent to each other may mean that at least some components, among components, are in contact with each other. For example, an opening, exposing a pad, may be exposing a pad from a resist layer, and a surface treatment layer or the like may be further disposed on the exposed pad.

As used herein, being disposed in a through-portion or a through-hole may include not only a case in which an object is completely disposed in the through-portion or the through-hole, but also a case in which a portion of an object protrudes upwardly or downwardly in cross-section. For example, in plan view, a case in which an object is disposed in the through-portion or the through-hole may be determined in a broader sense.

As used herein, a process error or a positional deviation occurring in a manufacturing process, an error in measurement, and the like may be included. For example, “substantially the same direction” may include not only “completely the same direction,” but also “approximately the same direction.” In addition, “substantially flat” may include not only “completely flat,” but also “approximately flat. ” For example, “a substantially flat shape” may describe a flat surface that deviates less than 1° (or other suitable tolerances) with respect to the horizontal axis or the vertical axis. In addition, “having a substantially specific shape” may include not only “having a completely specific shape,” but also “having an approximately specific shape. ” For example, “a substantially round shape” may describe a curved surface that is an arc of a circle or an oval. The phrase “substantially coplanar” may refer being in the same plane or in a plane that deviates from a reference plane by 1° or other suitable tolerances.

As used herein, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper”and “lower”may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, each of a thickness, a width, a length, a depth, a line width, a space, a pitch, a separation distance, a surface roughness, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. When the value is not constant, the value may be determined as an average value of values measured at five arbitrary points. In this case, when a component does not have a predetermined value, the value may be determined as an average value of values measured at arbitrary five points. Other methods and/or tools appreciated by one of ordinary skill in the art, even if not described in the present disclosure, may also be used.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a glass layer having a first surface and a second surface opposing each other in a first direction;
a through-via passing through at least a portion of a space between the first and second surfaces of the glass layer, the through-via having a first end and a second end opposing the first end in the first direction;
a first pad embedded in the first surface of the glass layer, the first pad connected to the first end of the through-via; and
a second pad protruding from the second surface of the glass layer, the second pad connected to the second end of the through-via.

2. The printed circuit board of claim 1, wherein each of a first surface and a second surface of the first pad has a substantially rounded shape.

3. The printed circuit board of claim 2, wherein each of a first surface and a second surface of the second pad has a substantially flat shape.

4. The printed circuit board of claim 1, wherein the first end of the through-via has a step portion with respect to the first surface of the glass layer.

5. The printed circuit board of claim 4, wherein the second end of the through-via is substantially coplanar with the second surface of the glass layer.

6. The printed circuit board of claim 1, wherein
the first pad includes a first seed layer that is disposed between the first end of the through-via and the second surface of the first pad, and
the second pad includes a second seed layer that is disposed between the second end of the through-via and the second surface of the second pad.

7. The printed circuit board of claim 1, further comprising:
a first insulating body disposed on the first surface of the glass layer; and
a second insulating body disposed on the second surface of the glass layer,
wherein the first insulating body is thicker than the second insulating body in the first direction.

8. The printed circuit board of claim 7, further comprising:
a plurality of first wiring layers respectively disposed on or in the first insulating body; and
a second wiring layer disposed on or in the second insulating body,
wherein the plurality of first wiring layers has more layers than the second wiring layer.

9. The printed circuit board of claim 8, comprising:
a plurality of first via layers respectively disposed in the first insulating body, the plurality of first via layers respectively connected to one or more first wiring layers among the plurality of first wiring layers; and
a second via layer disposed in the second insulating body, the second via layer connected to the second wiring layer,
wherein the plurality of first via layers has more layers than the second via layer.

10. The printed circuit board of claim 9, wherein
the glass layer has a cavity passing through at least a portion of the glass layer from the first surface of the glass layer in the first direction,
the printed circuit board further comprises a first electronic component, the first electronic component is connected to the one or more of the plurality of first wiring layers through one or more of the plurality of first via layers, and at least a portion of the first electronic component is disposed in the cavity, and
the first insulating body covers at least a portion of the first electronic component, and fills at least a portion of the cavity.

11. The printed circuit board of claim 9, further comprising:
a first resist layer disposed on the first insulating body, the first resist layer covering at least a first portion of an outermost first wiring layer in the first direction among the plurality of first wiring layers, the first resist layer does not cover at least a second portion of the outermost first wiring layer in the first direction;
a second resist layer disposed on the second insulating body, the second resist layer covering at least a first portion of the second wiring layer, the second resist layer does not cover at least a second portion of an outermost second wiring layer;
a first electrical connection metal disposed on the first resist layer;
a second electronic component disposed on the first resist layer, the second electronic component connected to the second portion of the outermost first wiring layer through the first electrical connection metal; and
a second electrical connection metal disposed on the second resist layer, the second electrical connection metal connected to the second portion of the outermost second wiring layer.

12. The printed circuit board of claim 1, further comprising:
a frame having a through-portion,
wherein at least a portion of the glass layer is disposed in the through-portion, and
a space between the frame and the glass layer includes a filler that fills the space.

13. The printed circuit board of claim 12, wherein the frame continuously surrounds the glass layer.

14. The printed circuit board of claim 12, wherein the through-portion has a continuous wall surface.

15. The printed circuit board of claim 1, wherein, in the first direction, the first end of the through-via is offset from the first surface of the glass layer.

16. A printed circuit board comprising:
a glass layer having a first surface and a second surface opposing each other in a first direction;
a through-via passing through at least a portion of a space between the first and second surfaces of the glass layer, the through-via having a first end and a second end opposing the first end in the first direction;
a first pad disposed on the first surface of the glass layer, the first pad connected to the first end of the through-via; and
a second pad disposed on the second surface of the glass layer, the second pad connected to the second end of the through-via,
wherein the first pad and the second pad are asymmetrical with respect to each other and with respect to a central line between the first surface and the second surface of the glass layer.

17. The printed circuit board of claim 16, wherein a distance between the first pad and the central line in the first direction is shorter than a distance between the second pad and the central line in the first direction.

18. The printed circuit board of claim 16, wherein a surface of the first pad, connected to the first end of the through-via, has a substantially rounded shape, and a surface of the second pad, connected to the second end of the through-via, has a substantially flat shape.

19. The printed circuit board of claim 16, wherein
a first seed layer is disposed between the first pad and the through-via, and
a second seed layer is disposed between the second pad and the through-via.
